(19) United States
(12) Patent Application Publication
(10) Pub. No.: US 2012/0098132 A1
(43) Pub. Date: Apr. 26, 2012

(54) SEMICONDUCTOR DEVICE AND METHOD OF MANUFACTURING THE SAME

(75) Inventors: Cheol Hwan PARK, Icheon-si (KR); Ho Jin Cho, Seongnam-Si (KR); Dong Kyun Lee, Seoul (KR)

(73) Assignee: Hynix Semiconductor Inc., Icheon (KR)

(21) Appl. No.: 13/279,546

(22) Filed: Oct. 24, 2011

(30) Foreign Application Priority Data
Oct. 25, 2010 (KR) 10-2010-0104312

(51) Int. Cl. H01L 29/43; H01L 21/28

(52) U.S. Cl. 257/745; 438/604; 257/E29.139; 257/E21.158

(57) ABSTRACT

A semiconductor device with a stable structure having high capacitance by changing the pillar type storage node structure and a method of manufacturing the same are provided. The method includes forming a sacrificial layer on a semiconductor substrate including a storage node contact plug, etching the sacrificial layer to form a region exposing the storage node contact plug, forming a first conductive material within an inner side of the region, burying a second conductive material within the region in which the first conductive material is formed, and removing the sacrificial layer to form a pillar type storage node.

### CROSS-REFERENCES TO RELATED APPLICATION

The present application claims priority to Korean patent application number 10-2010-0104312 filed on 25 Oct. 2010, which is incorporated by reference in its entirety.

### BACKGROUND OF THE INVENTION

1. Technical Field

The present invention relates to a semiconductor device and a method of manufacturing the same, and more particularly, to a semiconductor device including a storage node and a method of manufacturing the same.

2. Related Art

In recent years, the critical dimension (CD) and the unit cell area of a semiconductor device have been reduced as integration degree has increased. Thus, an area in which a cell capacitor is formed has also been reduced. However, since a capacitor has to ensure sufficient capacitance in a unit cell, various methods of forming capacitors having high capacitance in a narrow area have been suggested. Among them, studies on high dielectric material (high-k) have been developed as a method of ensuring high capacitance. In addition, techniques for stably forming a capacitor without causing defects in a semiconductor device having a large aspect ratio have been developed. However, it is difficult to stably form a capacitor structure in a semiconductor device having a design rule below 50 nm.

In the related art, cylinder type capacitors have been introduced to ensure capacitor area per unit cell. However, this is limited to increasing a planar area and thus, capacitors having a pillar structure have also been suggested. In pillar type capacitors, a capacitor having a high height or having a double stacking structure has been used.

FIGS. 1A to 1C are views illustrating a semiconductor device and a method of fabricating the same according to the related art.

Referring to FIG. 1A, a stacking structure of an etch stop layer 20, a first sacrificial layer 25, a second sacrificial layer 30 and a third sacrificial layer 40 is formed on an interlayer insulating layer 10 including a storage node contact plug 15. Then, the stacking structure is etched to form a storage node region 45 exposing storage node contact plug 15.

Referring to FIG. 1B, a conductive material is formed on the interlayer insulating layer 10 including the storage node region 45 and then a chemical mechanical polishing (CMP) or etch back process is performed until the third sacrificial layer 40 is exposed, thereby separating the conductive material formed within the storage node region 45 to form a lower electrode 50. The conductive material may include a titanium nitride (TiN) layer.

Next, referring to FIG. 1C, a wet dip out process is performed to remove the first sacrificial layer 25, the second sacrificial layer 30 and the third sacrificial layer 40.

In the related art, as described above, a TiN layer fills the pillar structure to form a pillar type capacitor. However, as the TiN layer increases to be several hundred Å thick, film stress increases, causing separation due to interface stress between the etch stop layer 20 and the lower electrode 50. Agglomeration of the TiN layer, caused by a subsequent thermal process, increases the separation. When the sacrificial layers 25, 30 and 40 of the storage node are removed by a wet dip out process, a wet etchant penetrates into the space between the TiN layer of the lower electrode 50 and the etch stop layer 20 and a TiSix layer formed between the TiN layer and the storage node contact plug 15 are removed so that the capacitor is electrically disconnected. Thus the capacitor cannot perform its function. In addition, due to generation of a bunker defect, the storage node is not stably formed and may incline at an angle, collapse, or fracture. This causes electrical short circuits during operation of the device resulting in device failure and reduced yield.

### SUMMARY

According to one aspect of an exemplary embodiment, a semiconductor device includes a pillar type storage node coupled to a storage node contact plug. The pillar type storage node includes a first conductive material and a second conductive material.

The first conductive material includes a composite material including a first material and a second material, the first material is selected from the group consisting of Si, C, Al, Ge, and a combination thereof, and the second material is selected from the group consisting of TiN, TaN, WN, Pt, Ru, AlN, and a combination thereof.

The second conductive material includes a material selected from the group consisting of SiGe, W, and a combination thereof.

According to another aspect of an exemplary embodiment, a semiconductor device, comprising: a pillar type storage node coupled to a storage node contact plug, the pillar type storage node includes: a cylinder type first conductive material; and a second conductive material, wherein the cylinder type first conductive material is disposed at a bottom and at sidewalls of the second conductive material.

The first conductive material includes a composite including a first material and a second material, wherein the first material is selected from the group consisting of Si, C, Al, Ge, and a combination thereof, and wherein the second material is selected from the group consisting of TiN, TaN, WN, Pt, Ru, AlN, and a combination thereof.

The first conductive material has a thickness of 10 to 200 Å. The second conductive material includes a material selected from the group consisting of SiGe, W and a combination thereof.

According to another aspect of an exemplary embodiment, a method of manufacturing a semiconductor device, comprising: forming a storage node contact hole over a semiconductor substrate so that the storage node contact hole exposes a storage node contact plug; and forming a pillar type storage node, wherein a first conductive material and a second conductive material fill the storage node contact hole.

The forming the storage node contact hole includes: forming a sacrificial layer over the semiconductor substrate; and etching the sacrificial layer to expose the storage node contact plug.

The first conductive material includes a composite including a first material and a second material, wherein the first material is selected from the group consisting of Si, C, Al, Ge, and a combination thereof, and wherein the second material is selected from the group consisting of TiN, TaN, WN, Pt, Ru, AlN, and a combination thereof.

The second conductive material includes a material selected from the group consisting of SiGe, W, and a combination thereof. The forming the second conductive material includes using SiH₄, Si₂H₆, SiCl₄, Si₃H₈, or TSA as a silicon source gas and N₂ or Ar-based GeH₄ as a germanium source gas, wherein a concentration of Ge of SiGe is 10 to 90%, wherein a concentration of Ge of SiGe is 30 to 50%.

Filling the storage node contact hole with the second conductive material includes crystallizing the second conductive material using a material selected from the group consisting of BCl₃, B₂H₆, PH₃, and a combination thereof as a source gas.

Filling the storage node contact hole with the second conductive material is performed at a temperature of 200 to 500° C. under a pressure of 0.1 to 10 Torr.

The method further comprising, after the forming the pillar type storage node, performing a wet dip out process to remove the sacrificial layer.

According to another aspect of an exemplary embodiment, A method of manufacturing a semiconductor device, comprising: forming a cylinder type first conductive material over a semiconductor substrate coupled to a storage node contact plug; and forming a second conductive material at sidewalls and at a bottom of the first conductive material to form a pillar type storage node.

The forming the cylinder type first conductive material includes: forming a sacrificial layer over the semiconductor substrate; etching the sacrificial layer to form a region exposing the storage node contact plug such that the region includes the exposed storage contact plug; and depositing a first conductive material at a sidewall and over a bottom of the region.

The forming the cylinder type first conductive material includes forming the first conductive material by combining a material selected from the group consisting of Si, C, Al, Ge, and a combination thereof with a material selected from the group consisting of TiN, TaN, WN, Pt, Ru, AlN, and a combination thereof.

The forming the first conductive material layer includes forming the first conductive material layer to a thickness of 10 to 200 Å.

The forming the second conductive material includes using a material selected from the group consisting of SiGe, W and a combination thereof.

The forming the pillar type storage node further includes removing the sacrificial layer through a wet dip out process.

According to another aspect of an exemplary embodiment, A method of manufacturing a semiconductor device, comprising: forming a sacrificial layer over a semiconductor substrate including a storage node contact plug; etching the sacrificial layer to form a region exposing the storage node contact plug; forming a first conductive material at a sidewall and over a bottom of the region; forming a second conductive material over the first conductive material; and removing the sacrificial layer to form a pillar type storage node.

The forming the sacrificial layer includes using a material selected from the group consisting of phosphorsilicate glass (PSG), boro-silicate glass (BSG), borophosphorsilicate glass (BPSG), undoped silicate glass (USG), tetraethyl orthosilicate (TEOS), polysilicon, SiGe, and a combination thereof.

The forming the first conductive material includes a composite including a first material and a second material, wherein the first material is selected from the group consisting of Si, C, Al, Ge, and a combination thereof, and wherein the second material is selected from the group consisting of TiN, TaN, WN, Pt, Ru, AlN, and a combination thereof.

The forming the first conductive material layer includes forming the first conductive material layer to a thickness of 10 to 200 Å. The forming the first conductive material includes performing a sequential flow deposition (SFD) or atomic layer deposition (ALD) method.

The forming the second conductive material includes using a material selected from the group consisting of SiGe, W and a combination thereof.

The forming the second conductive material includes using SiH₄, Si₂H₆, SiCl₄, Si₃H₈, or TSA as a silicon reactive gas and N₂ or Ar-based GeH₄ as a germanium reactive gas, wherein a concentration of Ge of SiGe is 10 to 90%, wherein a concentration of Ge of SiGe is 30 to 50%.

The forming the second conductive material over the first conductive material includes crystallizing the second conductive material using a material selected from the group consisting of BCl₃, B₂H₆, PH₃, and a combination thereof as a source.

The forming the second conductive material over the first conductive material is performed at a low temperature of 200 to 500° C. under a low pressure of 0.1 to 10 Torr.

The forming the pillar type storage node by removing the sacrificial layer includes removing the sacrificial layer through a wet dip out process.

These and other features, aspects, and embodiments are described below in the section entitled “DESCRIPTION OF EXEMPLARY EMBODIMENT.”

### BRIEF DESCRIPTION OF THE DRAWINGS

The above and other aspects, features, and other advantages of the subject matter of the present disclosure will be more clearly understood from the following detailed description with reference to the accompanying drawings, in which:

FIGS. 1A to 1C are cross-sectional views illustrating a semiconductor device and a method of manufacturing the same in the related art;

FIG. 2 is a cross-sectional view illustrating a semiconductor device according to an exemplary embodiment of the present invention; and

FIGS. 3A to 3G are cross-sectional views illustrating a method of forming a semiconductor device according to an exemplary embodiment of the present invention.

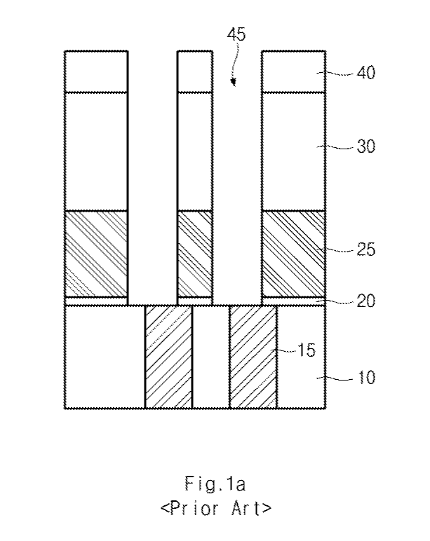

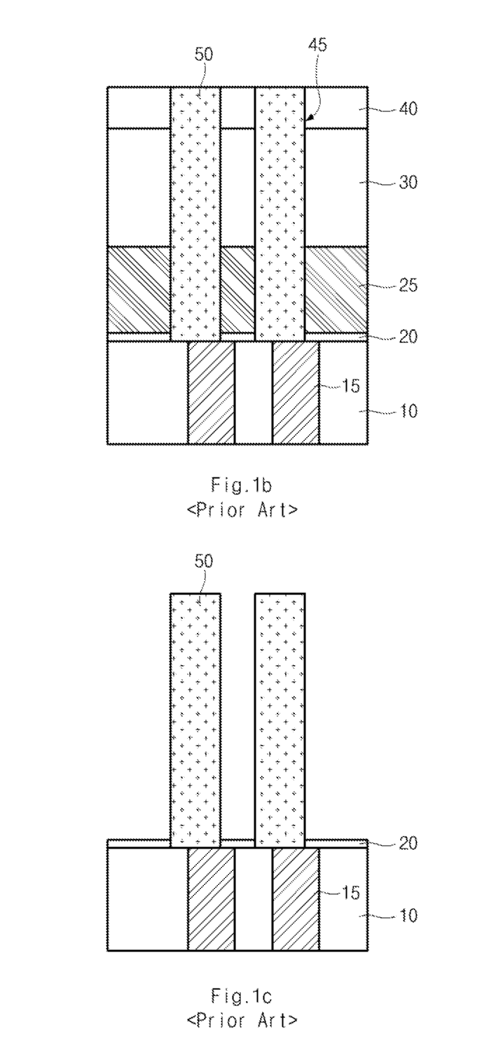

### DESCRIPTION OF EXEMPLARY EMBODIMENT

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein, but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other layer or substrate, or intervening layers may also be present.

Hereinafter, a semiconductor device and a method of manufacturing the same according to an exemplary embodiment of the present invention will be described in detail with reference to accompanying drawings.

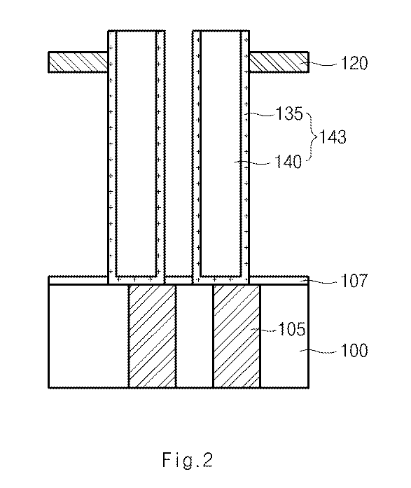

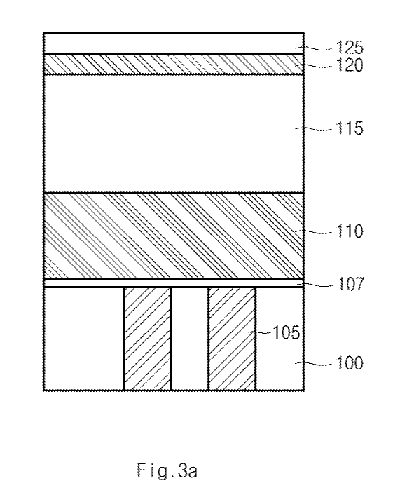

FIG. 2 is a cross-sectional view illustrating a semiconductor device according to an exemplary embodiment of the present invention.

Referring to FIG. 2, in an exemplary embodiment of the present invention, an interlayer insulating layer 100, including a storage node contact plug 105, is disposed over a semiconductor substrate (not shown). A pillar type bottom electrode 143 is formed over the interlayer insulating layer 100 such that it is coupled to the storage node contact plug 105. The storage node contact plug 105 may include polysilicon. In an embodiment, a TiSix (not shown) may be further formed over the storage node contact plug 105 to form an ohmic contact with the storage node contact plug 105.

The bottom electrode 143 includes a cylinder type first conductive material 135 disposed at a bottom and at sidewalls of a second conductive material 140. In an embodiment, the first conductive material 135 may be formed using any of Si, C, Al, Ge, and a combination thereof and a material selected from the group consisting of TiN, TaN, WN, Pt, Ru, AlN and a combination thereof. The first conductive material layer 135 may be formed of a TiN layer. The first conductive material layer 135 may be formed to a thickness of 10 to 200 Å. The second conductive material 140 may include a SiGe layer. The second conductive material 140 may be formed over the interlayer insulating layer 100, including the storage node contact plugs 105, to have a height of 10 to 1000 Å and preferably, 300 to 500 Å.

An etch stop layer 107 is disposed over the interlayer insulating layer 100 and between bottom electrodes 143. A supporting layer pattern 120 for preventing collapse of the bottom electrodes 143 is formed at a sidewall of the bottom electrode 143. In an embodiment, the supporting layer pattern 120 is disposed at an upper portion of bottom electrodes 143. The supporting layer pattern 120 may be formed to be a hole type or a line type when viewed in a plan view of a semiconductor device according to an exemplary embodiment of the present invention.

As described above, a storage node having a pillar structure and including the first conductive material 135 disposed at the bottom and at sidewalls of the second conductive material 140 is used to provide the capacitor with a stable structure, thus preventing collapse or fracture even when the bottom electrode 143 is formed to have a high height or a double stacking structure. The present invention is not limited to the above-described embodiment. The present invention may also be applied, for example, to a pillar type bottom electrode including the first conductive material 135 and the second conductive material 140 regardless of type.

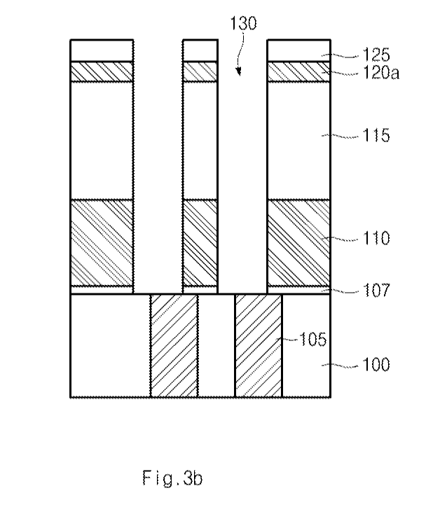

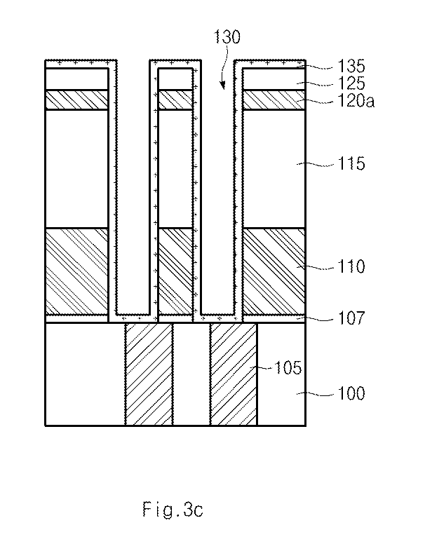

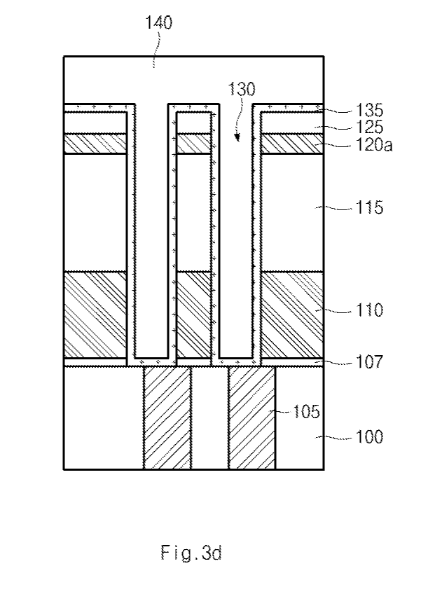

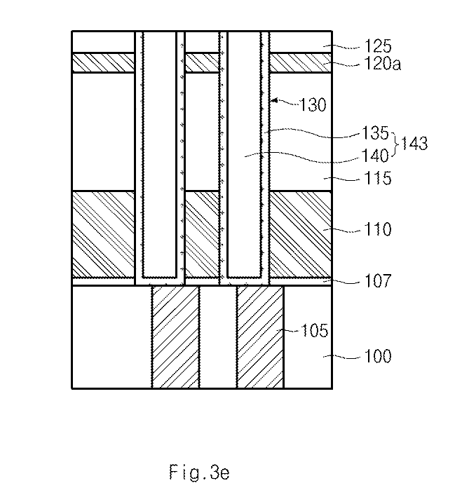

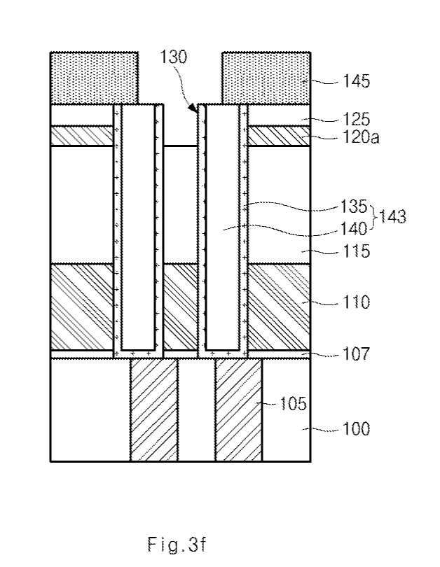

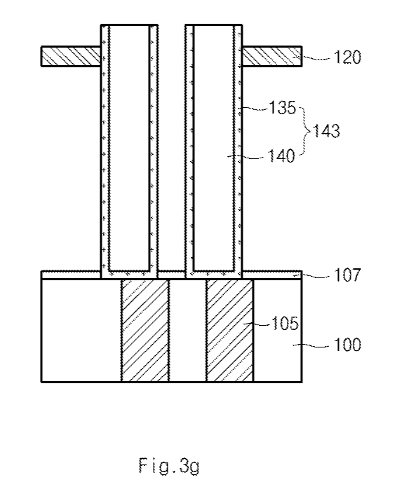

FIGS. 3A to 3G are cross-sectional views illustrating a method of manufacturing a semiconductor device according to an exemplary embodiment of the present invention.

Referring to FIG. 3A, an etch stop layer 107, a first sacrificial layer 110, a second sacrificial layer 115, a supporting layer 120, and a third sacrificial layer 125 are formed over an interlayer insulating layer 100 including a storage node contact plug 105. In an embodiment, the supporting layer 120 may be omitted.

In an embodiment, the storage node contact plug 105 may be formed of a material including a polyslicon, and the first to third sacrificial layers 110, 115 and 125 may include any of phosphorsilicate glass (PSG), boro-silicate glass (BSG), borophosphorsilicate glass (BPSG), undoped silicate glass (USG), tetraethyl orthosilicate (TEOS), polysilicon, SiGe and a combination thereof.

The etch stop layer 107 and the supporting layer 120 may be formed of a material including a nitride layer. For example, the etch stop layer 107 may be formed of a material including Si₃N₄. The etch stop layer 107 may be formed by a deposition method such as low pressure chemical vapor deposition (LP-CVD), atomic layer deposition (ALD) or plasma enhanced chemical vapor deposition (PE-CVD). The supporting layer 120 may be used to prevent collapse between bottom electrodes, which will be formed in a later process. An insulating layer having high etch selectivity to the sacrificial layer may be used to form the supporting layer 120. For example, the supporting layer 120 may be formed of a material selected from the group consisting of Si₃N₄, SiON, Si and a combination thereof.

Referring to FIG. 3B, a mask pattern (not shown) defining a storage node region is formed over the third sacrificial layer 125. The third sacrificial layer 125, the supporting layer 120, the second sacrificial layer 115, the first sacrificial layer 110 and the etch stop layer 107 are sequentially etched using the mask pattern as an etch mask to form a storage node region 130. In an embodiment, the storage node region 130 may be formed to expose the storage node contact plug 105. Alternatively, the storage node region 130 may also be formed to expose a portion of the storage node contact plug 105.

A titanium (Ti) layer (not shown) is deposited over an exposed surface of the storage node contact plug 105 and then an annealing process is performed. Polysilicon of the storage node contact plug 105 and the Ti layer react by the annealing process to form a TiSiₓ layer (not shown). Therefore, the TiSiₓ layer (not shown) is formed at an interface between the storage node contact plug 105 and the bottom electrode, which will be formed later, and thus contact resistance can be reduced.

Referring to FIG. 3C, a first conductive material 135 is deposited over the third sacrificial layer 125 including the storage node region 130 and the storage node region 130. The first conductive material 135 may be formed by combining a material selected from the group consisting of Si, C, Al, Ge, and a combination thereof with a material selected from the group consisting of TiN, TaN, WN, Pt, Ru, AlN, and a combination thereof. The first conductive material 135 may be preferably formed of a TiN layer. The first conductive material layer 135 may be formed to a thickness of 10 to 200 Å. Preferably, the first conductive material 135 layer may be as thin as possible while remaining within a range that will not result in deterioration of electrical characteristics.

In addition, the first conductive material 135 may be deposited by a sequential flow deposition (SFD) or an atomic layer deposition (ALD) method to minimize film stress. In an embodiment, the SFD method may be used to reduce a Cl concentration within the TiN layer by repeatedly performing an NH₃ annealing process for a short time after the TiN layer is deposited. For example, the SFD method repeatedly performs TiN layer deposition and an NH₃ annealing process.

Referring to FIG. 3D, a second conductive material 140 is formed over the entire resultant structure, including the storage node region 130 in which the first conductive material 135 is deposited. The second conductive material 140 may be formed of a material including any one selected from the group consisting SiGe, W and a combination thereof. The second conductive material 140 may be preferably formed of a SiGe layer. In addition, the second conductive material 140 may be preferably formed to a thickness of 10 to 1000 Å, so that the second conductive layer 140 fills the storage node region 130. More preferably, the second conductive material 140 may be formed to a thickness of 300 to 500 Å. In an embodiment, the second conductive material 140 may be formed at a low temperature of 400 to 500° C. to minimize thermal damage when the SiGe layer is deposited. More preferably, the second conductive material 140 may be formed at a temperature of 430 to 470° C. The second conductive material may be formed under a low pressure of 0.1 to 10 Torr to minimize film stress when the SiGe layer is deposited.

The second conductive material 140 is formed using SiH₄, Si₂H₆, SiCl₄, Si₃H₈, or TSA as a silicon (Si) source gas and N₂ or Ar-based GeH₄ as a germanium source gas. The second conductive material 140 is crystallized using a material selected from the group consisting of BCl₃, B₂H₆, PH₃, and a combination thereof as a source gas, so that the second conductive material 140 may serve as a conductor. In an embodiment, an ion implantation process may be performed together. Since the second conductive material 140 has a crystalline structure, thermal expansion and crystallization are not progressed to prevent stress. In order to improve the crystallization degree and conductivity of the SiGe layer, a concentration of Ge in the SiGe may be 10 to 90%, and preferably 30 to 50%. More preferably, the concentration of Ge in the SiGe may be 40% so that the conductivity of the SiGe layer can be maximized.

Referring to FIG. 3E, a planarization for the first conductive material 135 and the second conductive material 140 is performed until the third sacrificial layer 125 is exposed to separate the first conductive material 135 within the storage node region 130. In an embodiment, a chemical mechanical polishing (CMP) or an etch back process may be used as an etching process for the first conductive material 135 and the second conductive material layer 140.

Referring to FIG. 3F, a mask pattern 145 for patterning the supporting layer 120 is formed over the third sacrificial layer 125, the second conductive material 140 and the first conductive material 135. The mask pattern 145 may be formed to expose a portion between the storage node regions 130. In an embodiment, the mask pattern 145 may be formed to expose a portion of the storage node region 130. Subsequently, a portion of the third sacrificial layer 125 and the supporting layer 120 exposed by the mask pattern 145 is removed to form the supporting layer pattern 120a. In an embodiment, the supporting layer pattern 120a may be formed in a hole type or a line type.

Referring to FIG. 3G, the mask pattern 145 is removed. Next, a wet dip out process is performed to remove the third sacrificial layer 125, the second sacrificial layer 115 and the first sacrificial layer 110. In an embodiment, the wet dip out process may be performed in a single type or batch type wet cleaning equipment. The wet dip out process may be performed using a buffered oxide etchant (BOE) as an oxide etchant. A cleaning process using a cleaning (CLN) R, a CLN N, a fluorine rinse dry (FRD), a fluoric peroxide mixture (FPM) may be performed in-situ (at the same time) or ex-situ (separately).

Although not shown in FIG. 3G, a dielectric layer and an upper electrode are formed. The dielectric layer may include a material selected from the group consisting of Al₂O₃, HfO₂, ZrO₂, TiO₂, Ta₂O₅, BST, PZT and a combination thereof. The upper electrode may include a material selected from the group consisting of TiN, Ru, WN, AlN and a combination thereof.

In the related art, since the lower electrode is formed entirely of a TiN layer, damage between the lower electrode and an etch stop layer is caused by a wet cleaning solution. However, as illustrated in FIG. 3G, the first conductive material 135 is deposited on a bottom surface and at sidewalls of the bottom electrode 143 and the second conductive material 140 is surrounded by the first conductive material 135 so that damage in the interface between the lower electrode 143 and the etch stop layer 107 caused by a wet compound can be prevented.

The present invention is not limited to a pillar type lower electrode. The present invention may also be applied to any other shape of lower electrode so long as the lower electrode is formed including a first conductive material and a second conductive material.

As described above, the semiconductor device and the method manufacturing the same provides the following advantages. First, interface stress between the storage node and the etch stop layer can be prevented, thereby forming a storage node having a stable structure. Second, since inclining at an angle, collapse, or fracture of the storage node can be prevented, the storage node may be formed to have a high height or a double stacking structure.

The above embodiments of the present invention are illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

What is claimed is:

1. A semiconductor device, comprising:
a pillar type storage node coupled to a storage node contact plug,
wherein the pillar type storage node includes:
a first conductive material; and
a second conductive material.

2. The semiconductor device of claim 1, wherein the first conductive material includes a composite material including a first material and a second material,
wherein the first material is selected from the group consisting of Si, C, Al, Ge, and a combination thereof, and
wherein the second material is selected from the group consisting of TiN, TaN, WN, Pt, Ru, AlN, and a combination thereof.

3. The semiconductor device of claim 1, wherein the second conductive material includes a material selected from the group consisting of SiGe, W, and a combination thereof.

4. A semiconductor device, comprising:
a pillar type storage node coupled to a storage node contact plug,
wherein the pillar type storage node includes:
a cylinder type first conductive material; and
a second conductive material,
wherein the cylinder type first conductive material is disposed at a bottom and at sidewalls of the second conductive material.

5. The semiconductor device of claim 4, wherein the first conductive material includes a composite including a first material and a second material,
wherein the first material is selected from the group consisting of Si, C, Al, Ge, and a combination thereof, and
wherein the second material is selected from the group consisting of TiN, TaN, WN, Pt, Ru, AlN, and a combination thereof.

6. The semiconductor device of claim 4, wherein the first conductive material has a thickness of 10 to 200 Å.

7. The semiconductor device of claim 4, wherein the second conductive material includes a material selected from the group consisting of SiGe, W, and a combination thereof.

8. A method of manufacturing a semiconductor device, comprising:
forming a storage node contact hole over a semiconductor substrate so that the storage node contact hole exposes a storage node contact plug; and
forming a pillar type storage node,
wherein a first conductive material and a second conductive material fill the storage node contact hole.

9. The method of claim 8, wherein the forming the storage node contact hole includes:
forming a sacrificial layer over the semiconductor substrate; and
etching the sacrificial layer to expose the storage node contact plug.

10. The method of claim 8, wherein the first conductive material includes a composite including a first material and a second material,
wherein the first material is selected from the group consisting of Si, C, Al, Ge, and a combination thereof, and
wherein the second material is selected from the group consisting of TiN, TaN, WN, Pt, Ru, AlN, and a combination thereof.

11. The method of claim 8, wherein the second conductive material includes a material selected from the group consisting of SiGe, W, and a combination thereof.

12. The method of claim 11, wherein the forming the second conductive material includes using SiH₄, Si₂H₆, SiCl₄, Si₃H₈, or TSA as a silicon source gas and N₂ or Ar-based GeH₄ as a germanium source gas.

13. The method of claim 11, wherein a concentration of Ge of SiGe is 10 to 90%.

14. The method of claim 11, wherein a concentration of Ge of SiGe is 30 to 50%.

15. The method of claim 8, wherein filling the storage node contact hole with the second conductive material includes crystallizing the second conductive material using a material selected from the group consisting of BCl₃, B₂H₆, PH₃, and a combination thereof as a source gas.

16. The method of claim 8, wherein filling the storage node contact hole with the second conductive material is performed at a temperature of 200 to 500° C. under a pressure of 0.1 to 10 Torr.

17. The method of claim 9, the method further comprising, after the forming the pillar type storage node, performing a wet dip out process to remove the sacrificial layer.

18. A method of manufacturing a semiconductor device, comprising:
forming a cylinder type first conductive material over a semiconductor substrate coupled to a storage node contact plug; and
forming a second conductive material at sidewalls and at a bottom of the first conductive material to form a pillar type storage node.

19. The method of claim 18, wherein forming the cylinder type first conductive material includes:
forming a sacrificial layer over the semiconductor substrate;
etching the sacrificial layer to form a region exposing the storage node contact plug such that the region includes the exposed storage contact plug; and
depositing a first conductive material at a sidewall and over a bottom of the region.

20. The method of claim 18, wherein forming the cylinder type first conductive material includes forming the first conductive material by combining a material selected from the group consisting of Si, C, Al, Ge, and a combination thereof with a material selected from the group consisting of TiN, TaN, WN, Pt, Ru, AlN, and a combination thereof.

21. The method of claim 18, wherein the forming the first conductive material layer includes forming the first conductive material layer to a thickness of 10 to 200 Å.

22. The method of claim 18, wherein forming the second conductive material includes using a material selected from the group consisting of SiGe, W, and a combination thereof.

23. The method of claim 19, wherein forming the pillar type storage node further includes removing the sacrificial layer through a wet dip out process

24. A method of manufacturing a semiconductor device, comprising:
forming a sacrificial layer over a semiconductor substrate including a storage node contact plug;
etching the sacrificial layer to form a region exposing the storage node contact plug;
forming a first conductive material at a sidewall and over a bottom of the region;
forming a second conductive material over the first conductive material; and
removing the sacrificial layer to form a pillar type storage node.

25. The method of claim 24, wherein forming the sacrificial layer includes using a material selected from the group consisting of phosphorsilicate glass (PSG), boro-silicate glass (BSG), borophosphorsilicate glass (BPSG), undoped silicate glass (USG), tetraethyl orthosilicate (TEOS), polysilicon, SiGe, and a combination thereof.

26. The method of claim 24, wherein forming the first conductive material includes a composite including a first material and a second material,
wherein the first material is selected from the group consisting of Si, C, Al, Ge, and a combination thereof, and
wherein the second material is selected from the group consisting of TiN, TaN, WN, Pt, Ru, AlN, and a combination thereof.

27. The method of claim 24, wherein forming the first conductive material layer includes forming the first conductive material layer to a thickness of 10 to 200 Å.

28. The method of claim 24, wherein forming the first conductive material includes performing a sequential flow deposition (SFD) or atomic layer deposition (ALD) method.

29. The method of claim 24, wherein the forming the second conductive material includes using a material selected from the group consisting of SiGe, W, and a combination thereof.

30. The method of claim 29, wherein the forming the second conductive material includes using SiH₄, Si₂H₆, SiCl₄, Si₃H₈, or TSA as a silicon reactive gas and N₂ or Ar-based GeH₄ as a germanium reactive gas.

31. The method of claim 29, wherein a concentration of Ge of SiGe is 10 to 90%.

32. The method of claim 29, wherein a concentration of Ge of SiGe is 30 to 50%.

33. The method of claim 24, wherein forming the second conductive material over the first conductive material includes crystallizing the second conductive material using a material selected from the group consisting of BCl₃, B₂H₆, PH₃, and a combination thereof as a source.

34. The method of claim 24, wherein the forming the second conductive material over the first conductive material is performed at a temperature of 200 to 500° C. under a pressure of 0.1 to 10 Torr.

35. The method of claim 24, wherein the forming the pillar type storage node by removing the sacrificial layer includes removing the sacrificial layer through a wet dip out process.

36. A semiconductor device, comprising:
an underlying layer comprising a storage node contact pattern;
an etch stop pattern formed over the underlying layer;
a first lower electrode pattern coupled to the storage node contact pattern through the etch stop pattern; and
a second lower electrode pattern disposed between the etch stop pattern and the first lower electrode pattern.

37. The semiconductor device of claim 36, wherein the first lower electrode pattern is coupled to the storage node contact pattern through an opening formed in the etch stop pattern.

38. The semiconductor device of claim 36, wherein the second lower electrode pattern extends along a sidewall of the first lower electrode pattern.

39. The semiconductor device of claim 36, wherein the second lower electrode pattern extends between the first lower electrode pattern and the storage node contact pattern.

40. The semiconductor device of claim 36, wherein the second lower electrode pattern is configured to surround a sidewall and a bottom of the first lower electrode pattern.

41. The semiconductor device of claim 39, wherein the storage node contact pattern is formed of a first conductive material containing Si, Ge, Al, W, C, or a combination thereof.

42. The semiconductor device of claim 39, wherein the second lower electrode pattern includes TiN, TaN, WN, Pt, Ru, AlN, or a combination thereof.

43. The semiconductor device of claim 36, wherein the second lower electrode pattern is a lining pattern.

44. The semiconductor device of claim 36, wherein the second lower electrode pattern is thinner than the first lower electrode pattern.

45. The semiconductor device of claim 36, wherein the second lower electrode pattern is formed 10 to 200 Å thick.

46. The semiconductor device of claim 36, wherein the first lower electrode pattern includes a semiconductor material, a conductive material, or a combination thereof.

47. The semiconductor device of claim 36, wherein the first lower electrode pattern includes polysilicon.

48. The semiconductor device of claim 36, wherein the etch stop pattern includes silicon nitride.

49. The semiconductor device of claim 36, wherein an interface stress between the first lower electrode pattern and the etch stop pattern is lower than that between the second lower electrode pattern and the etch stop pattern.
